(19) United States
(12) Patent Application Publication
(10) Pub. No.: US 2004/0075450 A1
(43) Pub. Date: Apr. 22, 2004

(54) Current multiplex transmission of several sensor signals (vehicles)

(76) Inventors: Klaus-Peter Buge, Morlenbach (DE); Stephan Bruggemann, Frankfurt/Main (DE); Jochen Zachow, Schefflenz (DE); Jorg Eckrich, Wiesbaden (DE)

Correspondence Address: RADER, FISHMAN & GRAUER PLLC, 39533 WOODWARD AVENUE, SUITE 140, BLOOMFIELD HILLS, MI, 48304-0610, US

(21) Appl. No.: 10/332,223

(22) PCT Filed: Jun. 21, 2001
(86) PCT No.: PCT/EP01/06988

(30) Foreign Application Priority Data
Jul. 6, 2000 (DE) 100 32 408.8
Dec. 15, 2000 (DE) 100 62 839.7

(51) Int. Cl. G01R 27/08

(52) U.S. Cl. 324/710

(57) ABSTRACT

The present invention describes an arrangement (1) and a method for detecting and transmitting sensor signals, with one or more sensor inputs (33, 46), a processing unit (25, 29, 30, 45), at least one current source (21, 22) which modulates a signal current (32) that can be supplied to an evaluation unit (2) in dependence of a sensor signal from a first sensor element (7) guided through the processing unit, with the signal current being regulated at any time to the predetermined nominal value by means of the processing unit and/or the current source, and the arrangement comprises another signal input (33) for a second sensor (19) as well as a device for transmitting the other sensor signal by way of the signal current (26, 27, 34), with the second sensor that can be connected to the other signal input being furnished with a supply current by way of the other signal input.

The present invention further describes a sensor (19) for detecting the position of a mechanically slidable element (36, 36′, 37, 37′).

The invention also comprises an arrangement for detecting and transmitting sensor signals with a supply voltage-measuring device.

The present invention relates to arrangements according to the preambles of claims 1 and 14, a sensor according to the preamble of claim 8, as well as a method according to the preamble of claim 12.

Active sensors, which receive the signal from a rotating magnetic encoder or a generator wheel with a sensor element, are increasingly used for detecting the rotational speed in controlled brake systems for motor vehicles (ABS, TCS, ESP, etc.). The magnetic oscillation of the magnetic field induced by the encoder is sensed in a magneto-resistive sensor element, amplified and converted into two current levels by an electronic device. The frequency of the signal being produced this way is proportional to the encoder's rotational speed. A corresponding active sensor with a magneto-resistive incremental transducer is e.g. described in WO 98/09173. The sensor includes two signal lines that can be connected to a brake control unit. A serial interface of this type where the transmission of information is effected by modulation of the current exhibits advantages in terms of safety of operation. An embodiment of these known active sensors is equipped with an additional data channel for additional information. This permits the transmission of additional information such as the existing brake lining wear, forward/backward detection, etc. The additional signal of the prior art sensor is coded and transmitted in the pulse pauses by means of a current signal e.g. with an amplitude that is smaller than that of the current pulses for the rotational speed signal.

DE 196 50 935 discloses a circuit arrangement for an active rotational speed sensor that largely operates according to the principle described above. Thus, additional information such as brake lining wear can be transmitted by way of a current-modulated two-wire serial interface. The additional signals are transmitted by way of a sequence of rapidly consecutive pulses that are related to a transmitted sequence of optionally ‘0’ or ‘1’ conditions. An example for a signals' course of the sensor according to the prior art is shown in FIG. 2. The current pulses 16 are generated with each alternation of the magnetic direction of the encoder. Therefore, the distances between the pulses are an indicator of the angular speed \overline{ω} of the encoder. The basic current 11 is used for the constant current supply of the electronic components of the active sensor. The pulses for the additional signals 17, 17′, 17″ have a smaller amplitude (current level 12) than the rotational speed pulses and are triggered by the latter pulses.

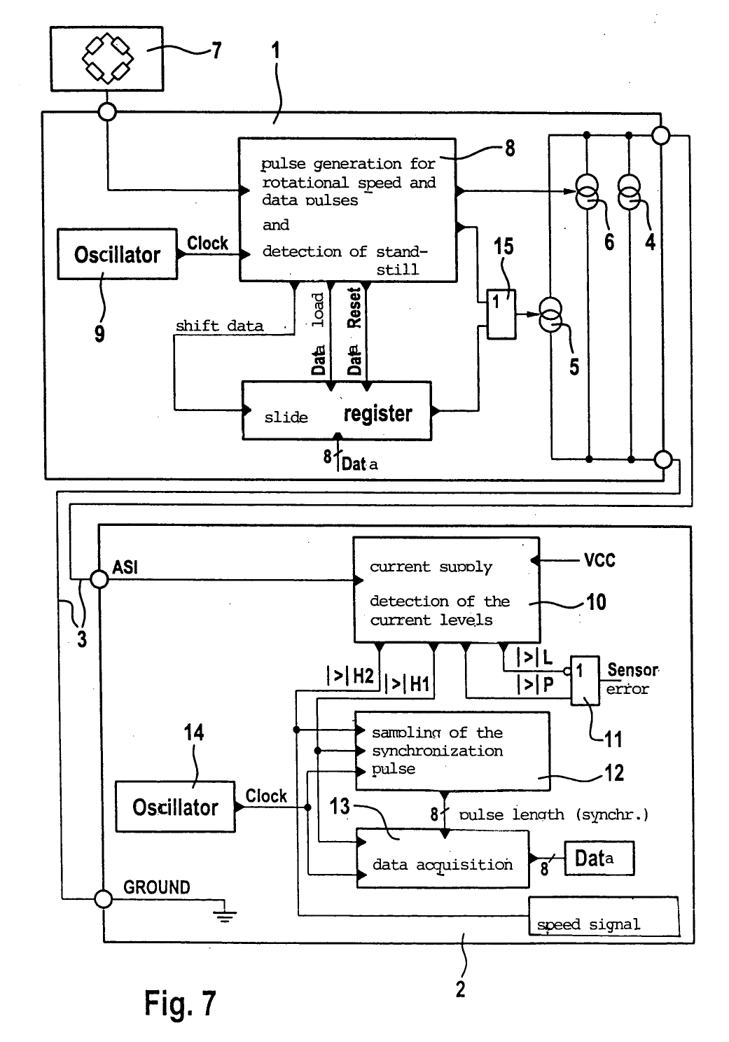

A circuit arrangement 1 for conditioning the sensor signals is illustrated in the top part of FIG. 7. The generation of the current protocol becomes apparent there by way of the current sources 5, 6, 4. The signal of a magneto-resistive rotational speed sensor is sent to a processing electronics 8 for the pulse generation acting on the current source 6. Current source 6 produces the rotational speed pulses. Current source 4 provides for the supply current. Current source 5 is used to produce the additional signals in the pauses between the rotational speed pulses and is actuated by way of an OR gate 15 by the processing electronics 8 or a slide register. The oscillator 8 produces a clock signal for the additional signals.

The sensor signals are transmitted to a brake control unit by way of the signal lines 3. An example for a circuit arrangement 2 that is comprised in the brake control unit and used to evaluate the current signal shows the bottom part of FIG. 7.

Additional information may be transmitted by way of the signal lines by means of the additional data. In prior art designs of active sensors, external signals can only be processed in the form of two conditions, 0 or 1. However, there is increasing need of extending the accuracy in brake wear detection, for example, from a purely digital detection to a continuous measurement of the degree of wear. In addition, there is the requirement of a particularly fail-safe measurement of these additional pieces of information. However, active sensors known in the art do not permit detecting the brake lining wear with a higher rate of accuracy because the extent of functions available would be exhausted.

It is another disadvantage of active arrangements for sensors known in the art that no measuring current of a defined magnitude is permanently available at an additional signal input of the arrangement for detection with a high degree of reliability in operation.

This object is achieved with an arrangement for detecting and transmitting sensor signals, especially a circuit arrangement for an active rotational speed sensor in motor vehicles, with one or more sensor inputs, a processing unit, at least one current source which modulates a signal current that can be supplied to an evaluation unit in dependence on a sensor signal guided through the processing unit, the said arrangement being characterized in that the signal current is regulated at any time to the predetermined nominal value by means of the processing unit and/or the current source, and the arrangement comprises another signal input for a second sensor as well as a device for transmitting the other sensor signal by way of the signal current, with the second sensor that can be connected to the other signal input being furnished with a supply current by way of the other signal input. The sensor element connected to the first input can be integrated on an assembly group of the above-described arrangement or may be arranged outside of the assembly group. It is, however, preferred that the sensor element is integrated on the assembly group of the arrangement of this invention.

According to the present invention, it is possible to provide a supply current for an external additional sensor while maintaining the specification for the sensor signal interface. The said current may either be deviated always, or only at defined points of time. Preferably, the signal current is deviated permanently, it being advantageous for reasons of an improved measuring accuracy to evaluate the measured quantity sensed by the additional sensor only in the duration of a rotational speed pulse.

The current source for generating the signal current may e.g. be realized by a current mirror in the simplest case. It may also be arranged for that for each type of signal a special current source is used that is especially provided for this type of signal.

The arrangement of the present invention is preferably equipped with a controllable current source.

A current supply of the arrangement of the present invention may take place by way of an additional voltage supply connection or by way of the signal lines. Most favorably, the arrangement does not have any other voltage supply connection so that the evaluation unit feeds the arrangement electrically by way of the signal lines that conduct the signal current.

The current is conducted to the evaluation unit by means of two wires in a so-called two-wire sensor. However, it is also possible to economize the second wire by a reliable ground connection (e.g. vehicle body).

In addition to a rotational speed sensor, further sensors used may e.g. be sensors for detecting the brake lining wear, the tire pressure, the temperature rise in the brake, or also status signals of the arrangement itself such as temperature, etc. Preferably, the second sensor is a sensor that is not accommodated directly in the area of the arrangement and is connected to the arrangement of the invention by way of supply cables of an appropriate length. In the case of a defect of the second sensor or the supply cables provided for it, it must be possible for the arrangement to detect this defect.

It is preferred in the present invention that the second sensor is a passive sensor without an electrical supply connection of its own. The current of the signal lines to the arrangement of the present invention is used for the operation of the additional sensor. This permits reliably detecting the above-mentioned defects in operation.

Favorably, the arrangement of this invention comprises a means in the processing unit and the current source means that is realized in particular by another current source or a controllable current source, for transmitting one or more coded, especially digitally coded, additional signals. As mentioned already, the additional signals may e.g. be binary coded signals of additional sensors and/or for status signals of the sensors or the arrangement. By means of the additional signals, the signal current can be modulated according to additional information (e.g. brake lining wear, status signals, direction of rotation, voltage level) that can be delivered to the processing unit. Advantageously, a modulation of the signal current for the additional signals is performed exclusively in the signal pauses of the sensor signal.

Suitably, the status signals are triggered by a rotational speed pulse. If, in the absence of rotational speeds, a rotational speed pulse was not generated for a long time, it may be arranged for to generate an auxiliary trigger pulse.

As has been described hereinabove, the second sensor may be fed by way of a signal line. It is favorable to this end to provide the supply current for the second sensor by means of a current branching means being comprised in the arrangement.

Advantageously, the current branching means may be arranged in the current path of the current source.

For the case described further hereinabove, i.e., that separate current sources are provided for each type of signal, it is possible to arrange the current branching means only in the current path of a current source.

The branching means preferably includes a current-measuring device in a first current branch, the said current-measuring device e.g. being a resistor in combination with a voltage-measuring device, as well as a connection for the second sensor in a second current branch. It is also possible, however, to employ another electrical component such as a sense FET that is suitable for measuring the current in lieu of a resistor element in the first current branch.

The measured quantity such as the brake lining wear, sensed by the second sensor, favorably modulates the current that flows through the second sensor. This current is suitably converted digitally by means of an evaluation circuit provided on the arrangement and is transmitted in the form of a coded additional signal by way of the signal current to an evaluation unit.

The second sensor connected to the other signal input is preferably provided to sense the position of a mechanically slidable element, such as a brake caliper in brake lining wear detection. The second sensor advantageously comprises an inductive component having an inductance that varies depending on the position of the slidable element.

Further, the present invention relates to a sensor for sensing the position of a mechanically slidable element, especially for detecting brake lining wear in a motor vehicle brake, including an evaluation circuit which is characterized in that the sensor includes two or more signal lines for transmitting a signal proportionally responsive to the position to a circuit arrangement, and the wheel sensor unit is fed with a supply current by way of the signal lines.

In a preferred aspect of the present invention, the sensor comprises an inductive component whose inductance varies according to the position of the slidable element, in particular according to the wear of friction elements in a wheel brake.

Appropriately, the slidable element is connected mechanically to the magnetic core and/or the coil in such a fashion that the position of the core in relation to the coil changes.

In another preferred aspect of a sensor of the present invention, the said sensor comprises a resistor element having a resistance that is variable in dependence on the slidable element, or a switch element that opens or closes at a defined predetermined position of the slidable element, or a capacitive component having a position-responsive capacitance.

It is likewise possible for the sensor of the invention to comprise a combination of travel-responsively variable resistors, capacitances, inductances, and switches.

The present invention further relates to a method of transmitting sensor signals to an evaluation unit by means of a signal current by way of an electric supply cable from the evaluation unit to an arrangement provided for transmitting the sensor signals. According to the present method, the signal of a rotational speed sensor is converted by means of an evaluation circuit and a current source into a sequence of current pulses having approximately the same amplitude and a speed-responsive pulse distance.

It is preferred that the pulse width is regularly smaller than the pulse width of the rotational speed signal from the sensor element. According to the method at issue, the arrangement is electrically fed with a basic current on the current conduction by the evaluation unit.

According to a preferred variation of the method, additional signals are additionally transmitted in a coded form in the pulse pauses by way of the current conduction by means of further pulses other than the rotational speed pulses.

According to the method of this invention, the signal current of the arrangement, especially the signal current for the rotational speed pulses, is divided into a measuring current 14 and a current for the electrical supply of one or more additional sensors.

The additional sensor may be fed electrically either on a permanent basis, or exclusively while defined types of pulses are produced by the arrangement. Favorably, the additional sensor(s) is/are fed electrically only during a current pulse.

Subsequently, another embodiment of an arrangement of the present invention for detecting and transmitting sensor signals will be described, wherein a rotational speed sensor signal of a motor vehicle wheel is converted into a signal that can be transmitted by two signal lines, and the supply voltage of the arrangement is received by way of the signal lines. The arrangement may favorably be an extension of the arrangement described hereinabove.

In another arrangement, the supply voltage applied to the signal lines is measured according to the present invention by means of a voltage-measuring device mounted on the arrangement. Advantageously, this permits checking whether there are high transition resistances in the signal lines leading to the arrangement, for example, due to line damage or deficient contacts. It can also be checked whether the voltage supply of the evaluation unit is operating reliably.

Preferably, an analog-/digital converter is provided in the arrangement converting the value of the supply voltage into an additional signal. There may also be provision of a switch element that produces a ‘high’ status signal or a ‘low’ status signal as an additional signal for a supply voltage lying in a defined voltage range. Besides, means may be provided permitting the transmission of the additional signal in the pulse pauses of the rotational speed signal by way of the signal lines.

In a particularly favorable manner, top and bottom limit values for voltages are determined in a memory in the arrangement, and it is checked in the arrangement whether the supply voltage lies within the allowable range predefined by these values. This information may then be transmitted as a status signal by way of one single bit.

Further favorable embodiments can be seen in the following description of Figures in which the invention is described in detail by way of examples.

In the drawings,

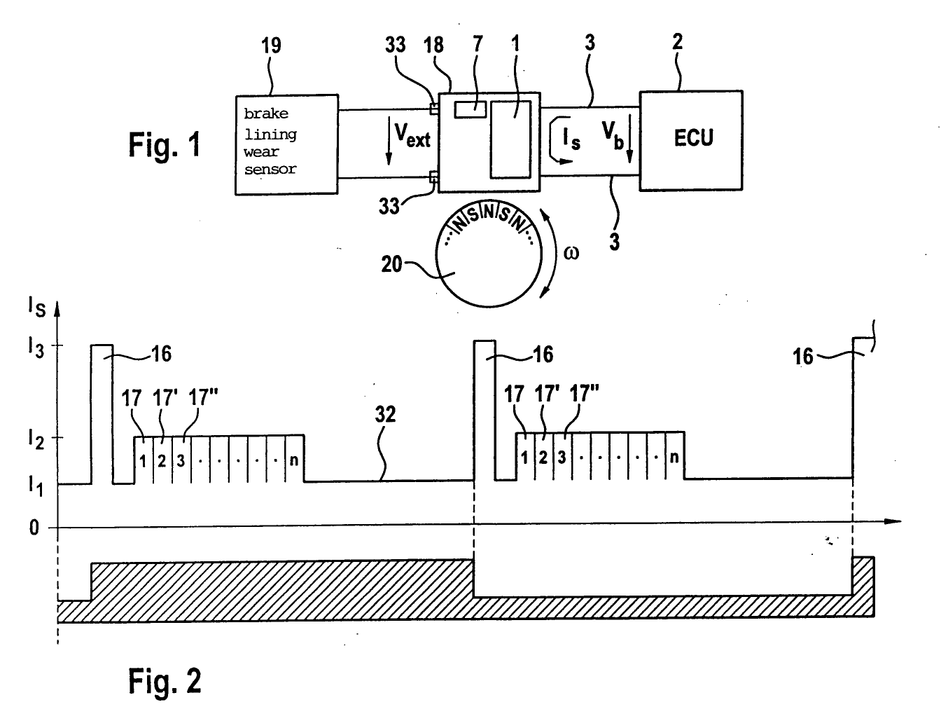

FIG. 1 is a view of an active rotational speed sensor according to the invention with a brake lining wear detection, said sensor being connected to a control unit.

FIG. 2 shows the signal course of the active rotational speed sensor of the present invention.

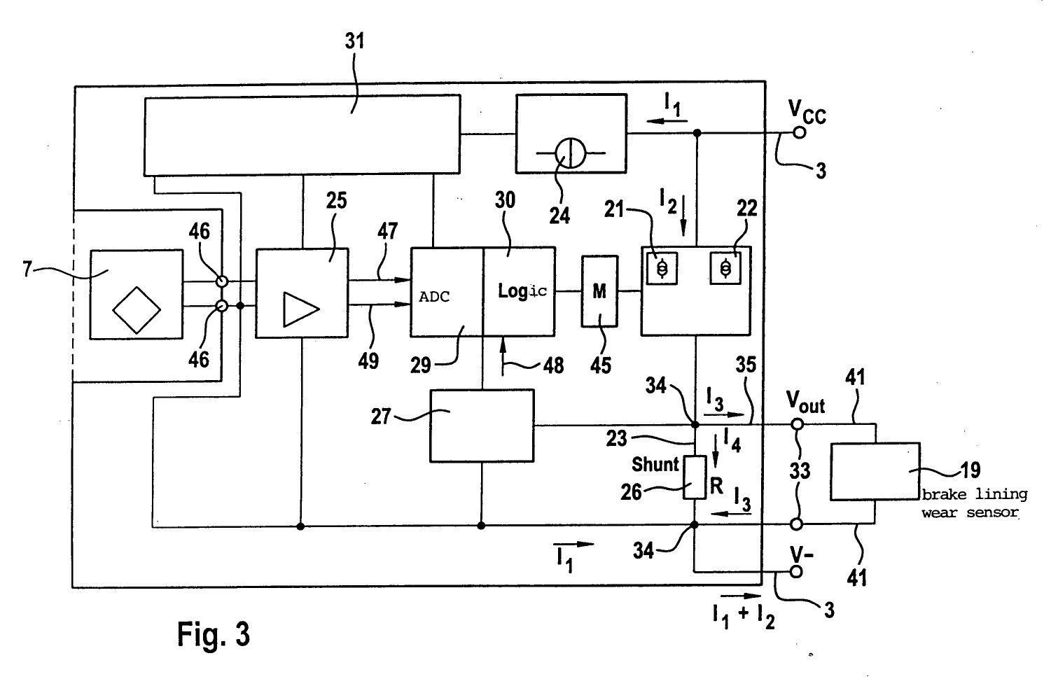

FIG. 3 is an arrangement of the invention for detecting and transmitting a sensor signal with a rotational speed sensor element 7 and a second sensor 19.

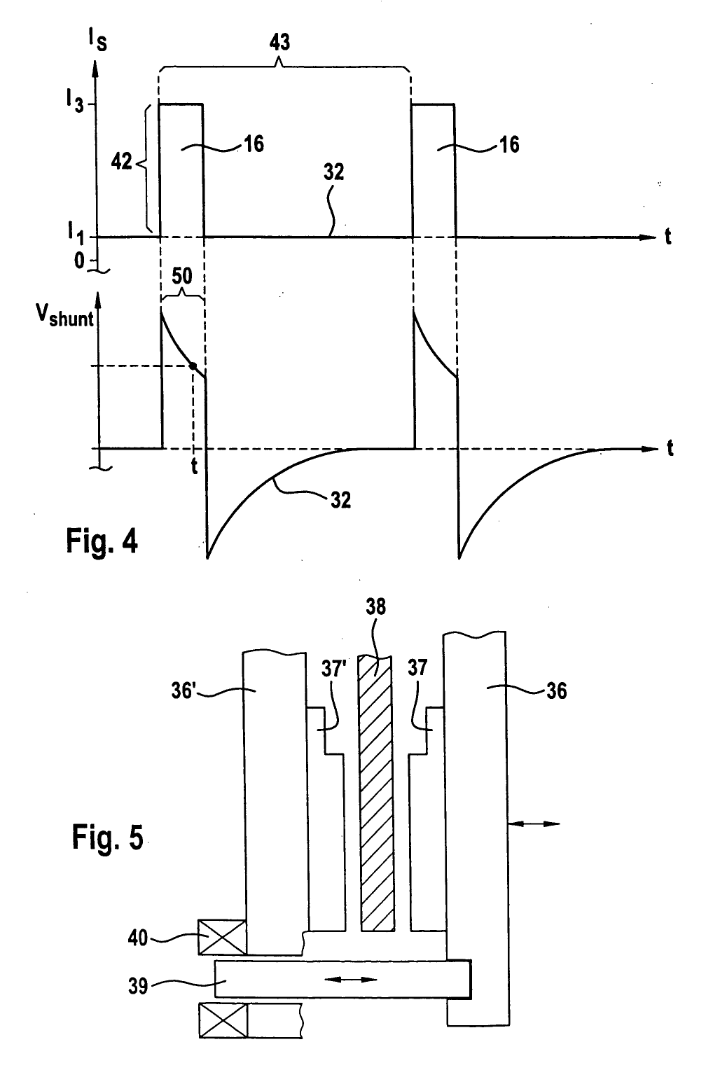

FIG. 4 shows the current course in the signal line of the arrangement in the top partial picture and the corresponding course of the voltage at the resistor 26 (shunt) in the bottom partial picture.

FIG. 5 shows a motor vehicle brake with a brake lining wear sensor according to the present invention.

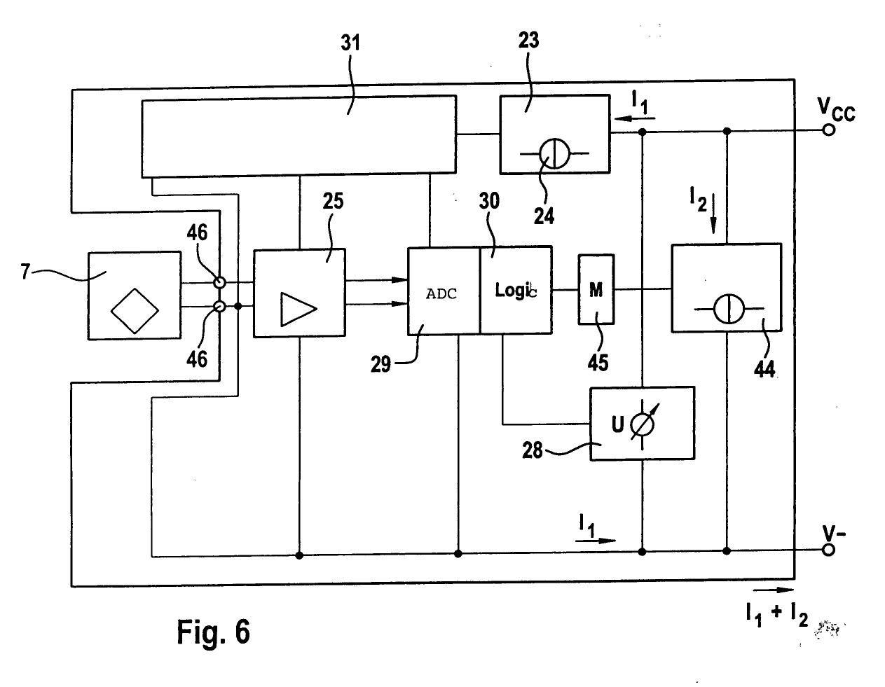

FIG. 6 is a view of an arrangement for detecting and transmitting a sensor signal with an additional monitoring of the operating voltage.

FIG. 7 shows a system for transmitting wheel rotational speed signals by means of an active two-wire sensor to a brake control unit of the state of the art.

FIG. 1 shows an active wheel speed sensor 18 with a rotational speed sensor element 7 and a circuit arrangement for evaluating and transmitting the rotational speed information received by encoder 20. The active rotational speed sensor includes additional signal inputs 33 for a brake lining wear sensor 19.

FIG. 2 illustrates an exemplary course for a current signal conducted to a brake control unit 2 by way of line 3. The position of the encoder beneath the rotational speed sensor element is shown schematically below the diagram. When the encoder changes its direction of magnetization, a short current pulse of the height 13 is produced. The distance 43 (FIG. 4) of the pulses contains the information about the angular speed of the encoder wheel. Additional data triggered by the rotational speed pulse is transmitted in the pulse pauses in the form of pulses of the height 12 associated with individual bits 1, 2, 3, . . . n in each case. All bits are set to the value ‘1’ in the example shown, the value ‘0’ would correspond to a current value of 11. The data may be coded in such a fashion that a defined current level corresponds to the information 0 or 1 at a defined point of time, but it is also possible to code the signal by means of leading or trailing edges (Manchester coded data). According to a preferred embodiment, a leading or trailing edge is recognized exactly when this event occurs in a time window triggered in dependence on the wheel pulse.

The basic current 11 (reference numeral 32) different from zero is taken into account for the energy supply of the active sensor.

FIG. 3 shows an arrangement for evaluating sensor signals and transmitting them to a control unit according to the present invention.

The current protocol is produced in a way similar to the arrangement illustrated in FIG. 7 by means of current sources 21, 22, 24. Current sources 21 and 22 generate the signal pulses, and current source 24 ensures a basic current 11 that is sent to a voltage stabilizing circuit 31 for generating the supply voltage of the arrangement. The signal of a magneto-resistive rotational speed sensor 7 is amplified by amplifier 25 and sent to a unit 29, 30 with an analog/digital converter 29 and a logic circuit 30. Additional information of the sensor element 7 may also be processed beside the rotational speed signal 49. Logic 30 drives a modulator 45 according to the rotational speed signals and the additional information, said modulator also acting upon a controllable current source 44 (FIG. 6) or actuating a separate current source 21 or 22 for each current level 12 and 13. The current signals are relayed in a per se known manner by way of the signal lines 3. Current source 6 generates the rotational speed pulses. Current source 4 provides for the supply current. Current source 5 is used to produce the additional signals in the pauses of the rotational speed pulses and is actuated by way of an OR gate 15 by the processing electronics 8 or a slide register. Oscillator 9 generates a timing signal for the additional signals.

The sensor signal is transmitted to a brake control unit by way of signal lines 3.

For connecting a brake lining wear sensor 19, the circuit arrangement in FIG. 3 includes additional connections 33 through which current is fed to the brake lining wear sensor. Signal current 12 receives the additional current 13 by way of a current branch 34. To ensure a signal generation by the current sources 21, 22 in a way independent of the load of sensor 19, a resistor element (shunt) 26 is arranged in parallel to the brake lining wear sensor. This permits maintaining the signal current prescribed by the current protocol at any time.

To measure the voltage drop at the resistor 26 that is proportional to the current in branch 23, an evaluation circuit 27 is arranged in parallel to the resistor and connected to the unit 29, 30 on the output side. The voltage of the resistor may be determined this way by the logic 30 at appropriate times.

If, for example, a brake lining wear sensor (as described hereinabove) with an inductive component is connected to the inputs 33, it may be judged, as shown in FIG. 4, at a time t after the generation of a rotational speed pulse 16 in which ratio the current subdivides at this time above the resistor 26 and the inductive component of the wear sensor. Due to the voltage Vₛₕᵤₙₜ in the curve area 50 decreasing to a greater extent at a higher rate of inductance, a value that is largely proportional to the degree of brake lining wear may be output by means of a logic circuit of a simple design. By way of the additional signals, this value may be transmitted in a definable resolution, e.g. in 2³=8 steps with 3 data bits, to the control unit of the brake control device by means of the analog/digital converter.

FIG. 5 illustrates schematically a brake lining wear sensor with a variable inductance mounted into a brake caliper. A ferromagnetic coil core 39 is moved in a coil 40 rigidly connected to a brake caliper. The inductance of the coil varies depending on the core's position. It is also possible to reverse the arrangement of coil and core, meaning that the coil is moved and the ferromagnetic core is rigidly connected to the brake caliper 36, 36′. The position of the core follows the position of the brake calipers relative to each other and is, thus, proportional to the sum of the thickness of brake lining 37, brake lining 37′, and the thickness of the brake disc 38.

According to the present invention, a non-contact travel measurement is possible at a point that is less critical with respect to temperature than is the case with the method known in the art.

FIG. 6 illustrates a circuit arrangement of an active sensor with a device for detecting an undervoltage operation and the output of a corresponding signal by means of the digital additional protocol.

By means of the additional undervoltage detection device 28 which is connected to the connections V_{cc} and V_, the development of transition resistances in the supply cables, e.g. due to corrosion in the plug, may be recognized. In this case, the supply voltage of the sensor reduces by the voltage that drops at the transition resistances. When the sensor voltage drops below a minimum value that is necessary for a safe sensor operation, this condition may be detected on account of a signal relayed to the connected control unit (ECU).

When the voltage falls under a predetermined threshold value, logic 30 will send a signal to the control unit (ECU) by way of the digital additional protocol. The voltage measured may also be converted in a binary form in the A/D converter 29 by the control unit 30 and transmitted to a control unit with the digital protocol of the sensor.

List of Reference Numerals:

| | |
|---|---|
| 1 | circuit arrangement for active rotational speed sensor |
| 2 | evaluation unit |
| 3 | signal lines |
| 4 | current source |
| 5 | current source |
| 6 | current source |
| 7 | rotational speed sensor element |
| 8 | signal conditioning |
| 9 | oscillator |
| 10 | switching block for current supply and detection of the |
| | current levels |
| 11 | error detection device |
| 12 | scanning device |
| 13 | data acquisition device |
| 14 | oscillator |
| 15 | OR-gate |
| 16 | rotational speed pulses |
| 17, 17′, 17″ | additional information pulses |
| 18 | sensor unit |
| 19 | brake lining wear sensor |
| 20 | encoder |
| 21 | current source for rotational speed signal |
| 22 | current source for additional signals |
| 23 | current branch for current measuring device |
| 24 | current source |
| 25 | amplifier |
| 26 | shunt |
| 27 | evaluation circuit |
| 28 | voltage-measuring device |
| 29 | analog/digital converter |
| 30 | digital logic device |
| 31 | circuit for voltage stabilization |
| 32 | signal basic current |
| 33 | signal input for brake lining wear sensor |
| 34 | current branching |
| 35 | current branch for brake lining wear sensor |
| 36, 36′ | brake caliper |
| 37, 37′ | brake lining |
| 38 | brake disc |
| 39 | coil core |
| 40 | coil |
| 41 | sensor lines for brake lining wear sensor |
| 42 | rotational speed pulse amplitude |
| 43 | pulse distance |
| 44 | controllable current source |
| 45 | modulator |
| 46 | rotational speed sensor inputs |
| 47 | additional information |
| 48 | additional information |
| 49 | rotational speed signal |
| 50 | curve area |

1. Arrangement (1) for detecting and transmitting sensor signals, especially a circuit arrangement for an active rotational speed sensor (18) in motor vehicles, with one or more sensor inputs (33,46), a processing unit (25, 29, 30, 45), at least one current source (21, 22) which modulates a signal current (32) that can be supplied to an evaluation unit (2) in dependence on a sensor signal from a first sensor element (7) guided through the processing unit,
characterized in that the signal current is regulated at any time to the predetermined nominal value by means of the processing unit and/or the current source, and the arrangement comprises another signal input (33) for a second sensor (19) as well as a device for transmitting the other sensor signal by way of the signal current (26, 27, 34), with the second sensor that can be connected to the other signal input being furnished with a supply current by way of the other signal input.

2. Arrangement as claimed in claim 1,
characterized in that a means (22) for transmitting one or more coded, in particular digitally coded, additional signals (17) is provided in the processing unit and the current source so that the signal current (32) is modulated according to additional information (47, 48) that can be sent to the processing unit.

3. Arrangement as claimed in claim 1 or 2,
characterized in that the supply current for the second sensor (19) is provided by means of a current branching means (33, 34, 26).

4. Arrangement as claimed in claim 3,
characterized in that the current branching means is arranged in the current path of the current source (21, 22).

5. Arrangement as claimed in claim 3 or 4,
characterized in that the branching means includes a current measuring device (26, 27) in a first current branch (23) as well as a connection (33) for the second sensor in a second current branch (35).

6. Arrangement as claimed in at least one of claims 2 to 5,
characterized in that the measured quantity sensed by the second sensor modulates the current that flows through the second sensor, and this current is digitally converted by means of an evaluation circuit (27, 29, 30) provided on the arrangement, and is transmitted in the form of a coded additional signal (17) by way of the signal current to an evaluation unit.

7. Arrangement as claimed in at least one of claims 1 to 6,
characterized in that the second sensor connected to the other signal input is provided for sensing the position of a mechanically slidable element (36, 36′, 37, 37′), with the said second sensor comprising an inductive component (39, 40) whose inductance varies according to the position of the slidable element.

8. Sensor (19) for detecting the position of a mechanically slidable element (36, 36′, 37, 37′), especially for detecting the brake lining wear in a motor vehicle brake, including an evaluation circuit (1),
characterized in that the sensor includes two or more signal lines (41) for transmitting a signal that is proportionally responsive to the position to a circuit arrangement (1), and the wheel sensor unit is fed with a supply current by way of the signal lines (41).

9. Sensor as claimed in claim 8,
characterized in that the sensor comprises an inductive component (39, 40) whose inductance varies according to the position of the slidable element.

10. Sensor as claimed in claim 9,
characterized in that the slidable element is connected mechanically to the magnetic core (39) and/or the coil (40) in such a fashion that a change in position of the core relative to the coil is achieved.

11. Sensor as claimed in claim 8,
characterized in that the sensor comprises a resistor element having a resistance that is variable in dependence on the slidable element, or a switch element that opens or closes at a defined predetermined position of the slidable element, or a capacitive component having a position-responsive capacitance, or a combination of travel-responsively variable resistors, capacitances, inductances and switches.

12. Method of transmitting sensor signals (16, 32, 17) to an evaluation unit (2) by means of a signal current by way of an electric supply line (3) from the evaluation unit (2) to an arrangement (1) provided for transmitting the sensor signals, wherein the signal of a rotational speed sensor (7) is converted by means of an evaluation circuit (25, 29, 30, 45) and a current source (21) into a sequence of current pulses (16) having approximately the same amplitude (42) and a speed-responsive pulse distance (43), the said arrangement being fed electrically by the evaluation unit with a basic current on the current conduction,
characterized in that the signal current (16, 17, 32) is divided into a measuring current and a current for the electrical supply of one or more additional sensors (19).

13. Method as claimed in claim 12,
characterized in that the additional sensor(s) is/are fed electrically only during a current pulse (16).

14. Arrangement (1) for detecting and transmitting sensor signals, wherein a rotational speed sensor signal of a motor vehicle wheel is converted into a signal that can be transmitted by two signal lines and the supply voltage of the arrangement is received by way of the signal lines (3), in particular as claimed in any one of claims 1 to 6,
characterized in that the supply voltage applied to the signal lines is measured by means of a voltage-measuring device (28) mounted on the arrangement.

15. Arrangement as claimed in claim 13,
characterized in that an analog/digital converter (29) is provided converting the value of the supply voltage into an additional signal, or a switch element which produces a ‘high’ status signal or a ‘low’ status signal as an additional signal (17) for a supply voltage lying in a defined voltage range, with means being provided permitting the transmission of the additional signal in the pulse pauses of the rotational speed signal (16) by way of the signal lines.
